(19) United States
(12) Patent Application Publication
(10) Pub. No.: US 2015/0338471 A1
(43) Pub. Date: Nov. 26, 2015

(54) RECONSTRUCTED BATTERY PACK APPLICABILITY DETERMINATION METHOD FOR USED SECONDARY BATTERY, AND RECONSTRUCTION METHOD FOR RECONSTRUCTED BATTERY PACK

(71) Applicant: Toyota Jidosha Kabushiki Kaisha, Toyota-shi Aichi-ken (JP)

(72) Inventors: Koichi Ichikawa, Kasugai-shi Aichi-ken (JP); Yasuhiro Takahashi, Miyoshi-shi Aichi-ken (JP); Masahiko Mitsui, Toyota-shi Aichi-ken (JP)

(21) Appl. No.: 14/694,556

(22) Filed: Apr. 23, 2015

(30) Foreign Application Priority Data
May 22, 2014 (JP) 2014-106174

(51) Int. Cl. G01R 31/36; H01M 10/42

(52) U.S. Cl. CPC G01R 31/3693; G01R 31/3662; H01M 10/4285

(57) ABSTRACT

A determination method for a used secondary battery is provided. The determination method includes: comparing an alternating-current internal resistance threshold with an alternating-current internal resistance value; and determining whether a first secondary battery is allowed to be applied to a reconstructed battery pack. The alternating-current internal resistance value is acquired by applying an alternating-current signal having a predetermined frequency to the first secondary battery. The first secondary battery is the used secondary battery intended for determination. The alternating-current internal resistance threshold is a value corresponding to a liquid retention amount threshold of the separator of the first secondary battery. The liquid retention amount threshold is a liquid retention amount of a separator of a second secondary battery. The second secondary battery is the same type as the used secondary battery intended for determination. The reconstructed battery pack is formed of a plurality of the used secondary batteries.

### INCORPORATION BY REFERENCE

The disclosure of Japanese Patent Application No. 2014-106174 filed on May 22, 2014 including the specification, drawings and abstract is incorporated herein by reference in its entirety.

### BACKGROUND OF THE INVENTION

1. Field of the Invention

The invention relates to a determination method of determining whether a used secondary battery is allowed to be applied to a reconstructed battery pack, and a reconstruction method for a reconstructed battery pack.

2. Description of Related Art

An electromotive vehicle, such as an electric vehicle and a hybrid vehicle, uses a secondary battery as a power supply. The hybrid vehicle includes a motor and an engine as a driving source for propelling the vehicle. A secondary battery is constructed by assembling a large number of battery cells together. A battery module is formed of a predetermined number of battery cells as one unit in terms of manufacturing and handling. A battery pack is constructed by combining a plurality of battery modules. A battery pack is mounted on a vehicle.

Japanese Patent Application Publication No. 2011-257314 (JP 2011-257314 A) describes that a charge/discharge current value and voltage value of each of battery cells of a secondary battery are detected, an internal resistance of each battery cell is acquired from the detected current value and voltage value and then degradation of each battery cell is determined on the basis of the corresponding internal resistance. It is known that there are temporal variations in the concentration of an electrolytic solution in charging or discharging, which may lead to erroneous determination that a battery has reached its service life.

### SUMMARY OF THE INVENTION

When a certain degree of degradation of a battery pack is estimated, for example, when a predetermined period has elapsed, the battery pack is replaced with a new one. From the viewpoint of efficient use of resources, when a battery pack is replaced and the used battery pack retrieved from a user is reusable as a whole, it is conceivable that the used battery pack is reused. When part of the used battery pack is reusable, it is conceivable that reusable battery modules are selected, a reconstructed battery pack is constructed by combining the selected reusable battery modules together as needed and then the reconstructed battery pack is reused.

When a user uses a used battery pack or a reconstructed battery pack, it is desirable to guarantee that the used battery pack or the reconstructed battery pack is usable for a predetermined period. In JP 2011-257314 A, it is determined whether each battery cell has degraded; however, a detailed degree of degradation is not determined, so a usable period of a battery pack to be reused is not clear.

The invention provides a reconstructed battery pack applicability determination method that is able to determine whether a used secondary battery is suitable for a reconstructed battery pack, and a reconstruction method that is suitable to select a used secondary battery applicable to a reconstructed battery pack and then reconstruct the reconstructed battery pack.

An aspect of the invention provides a determination method for a used secondary battery. The used secondary battery includes a separator. The determination method includes: comparing, by a computer, an alternating-current internal resistance threshold with an alternating-current internal resistance value; and determining, by the computer, whether a first secondary battery is allowed to be applied to a reconstructed battery pack. The alternating-current internal resistance value is acquired by applying an alternating-current signal having a predetermined frequency to the first secondary battery. The first secondary battery is the used secondary battery intended for determination. The alternating-current internal resistance threshold is a value corresponding to a liquid retention amount threshold of the separator of the first secondary battery. The liquid retention amount threshold is a liquid retention amount of a separator of a second secondary battery. The second secondary battery is a secondary battery of the same type as the used secondary battery intended for determination. The liquid retention amount threshold is a preset value. The reconstructed battery pack is a battery pack formed of a plurality of the used secondary batteries.

In the above aspect, the liquid retention amount threshold may be a value that is set on the basis of a rate of decrease in the liquid retention amount. The liquid retention amount threshold may be set as the liquid retention amount at a time point a predetermined degradation guarantee period before from the liquid retention amount at a time point at which is the second secondary battery is determined to degrade. The degradation guarantee period may be a period during which a usable state of the second secondary battery is guaranteed.

In the above aspect, the alternating-current internal resistance value may be a value that is set in a state where an alternating-current internal resistance value corresponding to the liquid retention amount threshold is set as the alternating-current internal resistance threshold. The liquid retention amount threshold may be a value that is set by obtaining in advance a correlation between the liquid retention amount and the alternating-current internal resistance value for the second secondary battery.

In the above aspect, the alternating-current internal resistance value may be acquired from a voltage response of the first secondary battery through application of the alternating-current signal to the first secondary battery. The alternating-current signal may be an alternating-current signal having a frequency at which a degree of correlation between the liquid retention amount and the alternating-current internal resistance value for the second secondary battery is larger than or equal to a preset value.

Another aspect of the invention provides a reconstruction method for a reconstructed battery pack. The reconstructed battery pack is a battery pack that is reconstructed of predetermined used secondary batteries. Each of the predetermined used secondary batteries is a used secondary battery that allows a guarantee against degradation. The secondary battery that allows a guarantee against degradation is selected from among a plurality of used secondary batteries that constitute a used battery pack by determining by a computer whether the used secondary battery is a secondary battery that allows a guarantee against degradation. The reconstruction method includes: setting, by the computer, an alternating-current internal resistance value corresponding to a liquid retention amount threshold of a first secondary battery as an alternating-current internal resistance threshold; selecting, by the computer, the used secondary battery, of which the alternating-current internal resistance value is smaller than the alternating-current internal resistance threshold, as the used secondary battery that allows a guarantee against degradation; and reconstructing a battery pack by using the selected used secondary batteries. The first secondary battery is the used secondary battery intended for determination. The liquid retention amount threshold is a value that is set on the basis of a rate of decrease in the liquid retention amount. The liquid retention amount threshold is set as the liquid retention amount at a time point a predetermined degradation guarantee period before from the liquid retention amount at a time point at which the second secondary battery is determined to degrade. The second secondary battery is a secondary battery of the same type as the used secondary battery intended for determination. The liquid retention amount is a liquid retention amount of a separator of the second secondary battery. The degradation guarantee period is a period during which a usable state of the second secondary battery is guaranteed. The alternating-current internal resistance value is the alternating-current internal resistance value of the first secondary battery.

In the above aspect, the alternating-current internal resistance value may be acquired for each of the plurality of used secondary batteries intended for determination. The computer may determine the used secondary battery, of which the alternating-current internal resistance value is smaller than the alternating-current internal resistance threshold, as a primary good product out of all the first secondary batteries. The computer may determine the used secondary battery, of which the alternating-current internal resistance value before being used for a reconstructed battery pack is smaller than the alternating-current internal resistance threshold, as a secondary good product out of the used secondary battery determined as the primary good product. The secondary good product may be a secondary battery that is usable for a reconstructed battery pack out of the primary good product.

In the above aspect, determination as to whether the primary good product is usable as the secondary good product may include determination as to whether overall specifications determined in advance to apply the used secondary battery to the reconstructed battery pack are satisfied.

According to the above aspect, it is possible to determine whether a used secondary battery is suitable for a reconstructed battery pack on the basis of a correlation with the liquid retention amount of the separator. With the configuration that uses the rate of decrease in the liquid retention amount, it is possible to select the used secondary battery that is not determined to be degraded over a period from the current time to the end time of the predetermined degradation guarantee period. Therefore, it is possible to provide the determination method that is further suitable for determination as to whether the used secondary battery is allowed to be applied to a reconstructed battery pack.

In addition, according to the other aspect, it is possible to provide the reconstruction method that is suitable for selecting the used secondary battery that is allowed to be applied to a reconstructed battery pack on the basis of a correlation with the liquid retention amount of the separator and then reconstructing the reconstructed battery pack.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a view that shows a flowchart that is used to carry out a determination method of determining whether a used secondary battery is applicable to a reconstructed battery pack according to an embodiment of the invention;

FIG. 2 is a graph that shows the correlation between a liquid retention amount and an elapsed time, which is used when a liquid retention amount threshold of a secondary battery is set in the determination method of determining whether the used secondary battery is applicable to a reconstructed battery pack according to the embodiment of the invention;

FIG. 3 is a Cole-Cole plot that shows the locus of a vector end at the time when the absolute value and phase of an alternating-current impedance value, which is an alternating-current internal resistance value of a secondary battery, change while a measuring frequency is used as a parameter;

FIG. 4 is a graph that shows the correlation between liquid retention amounts D obtained by disassembling secondary batteries and alternating-current internal resistance values X of the secondary batteries;

FIG. 5 is a graph that shows the correlation between a battery temperature and an annual temperature frequency and the correlation between a battery temperature and a rate of decrease in the liquid retention amount of a secondary battery in the determination method of determining whether a used secondary battery is applicable to a reconstructed battery pack according to the embodiment of the invention;

FIG. 6 is a view that shows a flowchart that is used to carry out a rebuilding method that is a reconstruction method for a reconstructed battery pack according to the embodiment of the invention; and

FIG. 7 is a view that shows, in time sequence, a state where a used battery pack is disassembled, a used secondary battery that allows a guarantee against degradation is selected and a reconstructed battery pack is reconstructed in accordance with the rebuilding method shown in FIG. 6.

### DETAILED DESCRIPTION OF EMBODIMENTS

Hereinafter, an embodiment of the invention will be described with reference to the accompanying drawings. In the following description, a determination method of determining whether a used secondary battery is applicable to a reconstructed battery pack may be referred to as determination method. A reconstruction method for a reconstructed battery pack may be referred to as reconstruction method or rebuilding method. The materials, numeric values, quantities, and the like, described below are only illustrative, and may be changed depending on the specifications of the determination method, the specifications of the reconstruction method, or the like. In the following description, like reference numerals denote equivalent elements in all the drawings. In the description of the specification, reference numerals described earlier are used where appropriate.

The description will be made on the assumption that the determination method is carried out when a rebuilt battery pack that is a reconstructed battery pack is constructed of used secondary batteries that constitute a used battery pack. The determination method may also be used as a determination method for constructing a reuse battery pack. The rebuilt battery pack is a battery pack that is reconstructed as a single battery pack by reusing used secondary batteries that are selected from among used secondary batteries of a plurality of used battery packs. The reuse battery pack is a battery pack that is restored by directly reusing all the used secondary batteries that constitute a single used battery pack. In the following description, the determination method is carried out twice when the rebuilt battery pack is reconstructed. In the reconstruction method for the rebuilt battery pack, the determination method may be carried out only once. The rebuilt battery pack is, for example, used as a power supply for a drive motor that is a driving source of an electric vehicle or hybrid vehicle.

Initially, the determination method will be described. After that, the reconstruction method for a reconstructed battery pack by using the determination method will be described.

Hereinafter, a secondary battery that uses a nickel-metal hydride battery will be described as the basic type of a secondary battery. The secondary battery is formed of some battery cells as a base unit. In each battery cell, an electrolytic solution is retained between a positive electrode and a negative electrode. The positive electrode and the negative electrode are separated from each other by a separator including an electrolyte membrane. As long as the secondary battery retains an electrolytic solution in separators, the secondary battery may be a secondary battery of a basic type other than the above structure. For example, the secondary battery may be a lithium ion secondary battery. The basic type is classified by a positive electrode material, a negative electrode material and an electrolyte.

Hereinafter, the case where the secondary battery is a battery module will be described. The battery module is formed by combining a plurality of battery cells, such as six battery cells, eight battery cells and 12 battery cells, in a stacked manner and then electrically connecting the battery cells in series with each other. When the battery cells are stacked, each of the electrodes may be shared between any adjacent battery cells. Therefore, the battery module cannot be disassembled in units of battery cell. Thus, when the secondary battery is reused, a unit of reuse is in units of battery module. A battery pack is formed by stacking a plurality of battery modules, such as 28 battery modules, and electrically connecting the plurality of battery modules in series with one another. The battery pack is also referred to as battery stack. The battery pack is mounted on a vehicle and is used. The battery stack is allowed to be disassembled into battery modules. In the following description, the secondary battery means a battery cell, a battery module, or a battery pack.

When the battery pack is mounted on a vehicle and is used, a liquid retention amount gradually decreases. The liquid retention amount is an electrolytic solution retention amount of the separator provided inside each battery cell. A gradual decrease in liquid retention amount becomes a cause of battery degradation. Therefore, according to the invention, whether a used secondary battery is suitable for a reconstructed battery pack is determined on the basis of the correlation between degradation of the battery and the liquid retention amount of the separator. Determination will be described below.

The used secondary battery is a used secondary battery, a secondary battery that has elapsed a predetermined guarantee period, or a secondary battery intended for determination as to whether a secondary battery allows a subsequent guarantee against degradation because of some reasons. When a used battery pack including used secondary batteries is retrieved from a user, or the like, by a battery pack reconstruction division, the battery pack reconstruction division determines whether each of the used secondary batteries is applicable to a reconstructed battery pack. As will be described later, the battery pack reconstruction division reconstructs a reconstructed battery pack by using used secondary batteries determined to be applicable to the reconstructed battery pack. The reconstruction division may be a group or company that reconstructs a reconstructed battery pack.

Hereinafter, when the guarantee period of a battery pack formed of a plurality of secondary batteries has elapsed or when the remaining guarantee period is short, it is determined whether a subsequent guarantee against degradation is allowed for each of the secondary batteries (battery modules) that constitute the battery pack.

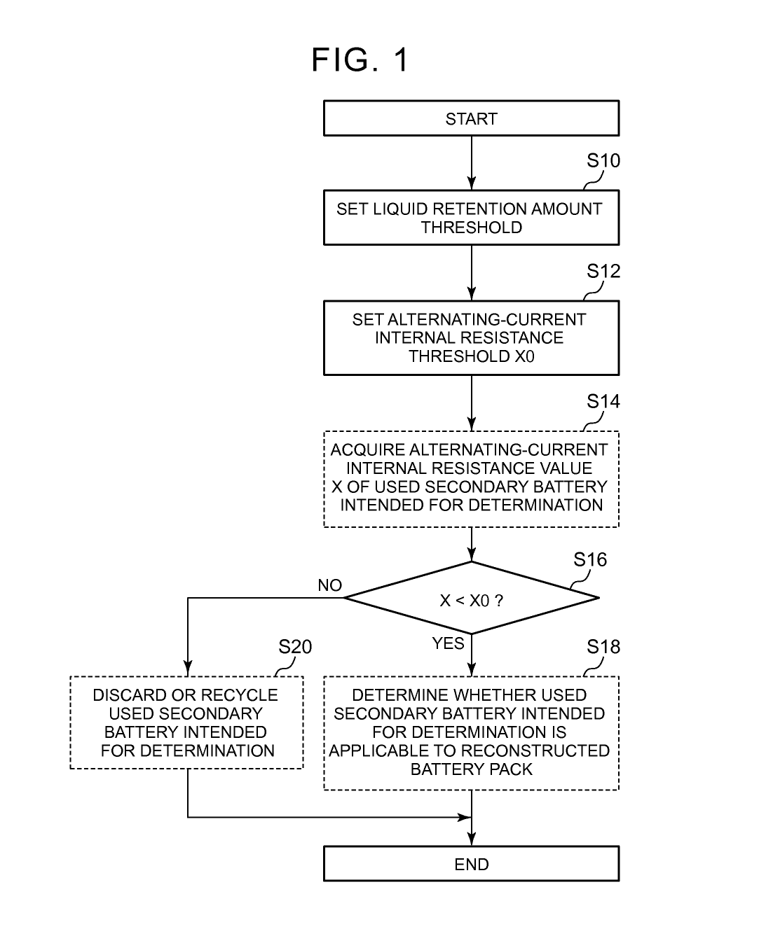

FIG. 1 shows a flowchart that is used to carry out the determination method according to the embodiment. In the flowchart shown in FIG. 1, steps including manual processing operation are surrounded by the dashed-line box. Steps surrounded by the continuous-line box are processes that are implemented by an adequate computer executing software. Specifically, the processes surrounded by the continuous-line box correspond to a reconstructed battery pack applicability determination program for a used secondary battery. This program may be divided into a pre-stage program and a post-stage program and executed separately on two computers. Part of steps surrounded by the continuous-line box may be implemented by hardware. Among the dashed-line boxes, determination of S18 (described later) may be executed on a computer.

In the determination method according to the embodiment, an alternating-current internal resistance value X of a used secondary battery intended for determination is acquired, and whether the used secondary battery is applicable to a reconstructed battery pack is determined on the basis of the result of comparison between an alternating-current internal resistance threshold X0 and the acquired alternating-current internal resistance value X. The alternating-current internal resistance threshold X0 corresponds to a liquid retention amount threshold set in advance for the liquid retention amount of the separator in a secondary battery of the same type as the used secondary battery intended for determination.

Specifically, to carry out reconstructed battery pack applicability determination for a used secondary battery, initially, a used secondary battery intended for determination is prepared. When the reconstructed battery pack applicability determination program for a used secondary battery starts up in a computer, the computer sets a liquid retention amount threshold on the basis of a user's input condition or a preset value (step S10). Hereinafter, step S is simply referred to as S.

When an operating time of the secondary battery extends, there occurs penetration of an electrolytic solution through a case forming the battery module, entry of water content into the positive electrode due to expansion of the positive electrode, consumption of water content due to a corrosion reaction of the negative electrode, or the like. As a result, the liquid retention amount of the separator decreases. When the liquid retention amount decreases, the internal resistance of the secondary battery increases, and the output of the secondary battery decreases. When the liquid retention amount excessively decreases, a secondary battery constituent material precipitates on the separator. A small short circuit tends to occur between the positive electrode and the negative electrode because of a precipitate, such as cobalt and manganese, on the separator. For this reason, a decrease in the liquid retention amount leads to degradation of the secondary battery. Therefore, when a secondary battery is reused, there is a liquid retention amount corresponding to a permissible value of degradation of the secondary battery. This is a liquid retention amount threshold.

The liquid retention amount threshold is set for the same type of a used secondary battery intended for determination. Therefore, the type of the used secondary battery intended for determination is identified, and then S10 is executed. The type of the used secondary battery is classified according to rated voltage specifications and rated charge/discharge current specifications within the nickel-metal hydride secondary battery. The secondary battery is assumed as a battery module formed of a plurality of battery cells. Therefore, the rated voltage specifications and the rated charge/discharge current specifications depend on the number of battery cells and the manner of connection of the battery cells in the battery module. In the present embodiment, the secondary battery of the same type means that the basic type, such as nickel-metal hydride battery, the rated voltage specifications and the rated charge/discharge current specifications all are the same.

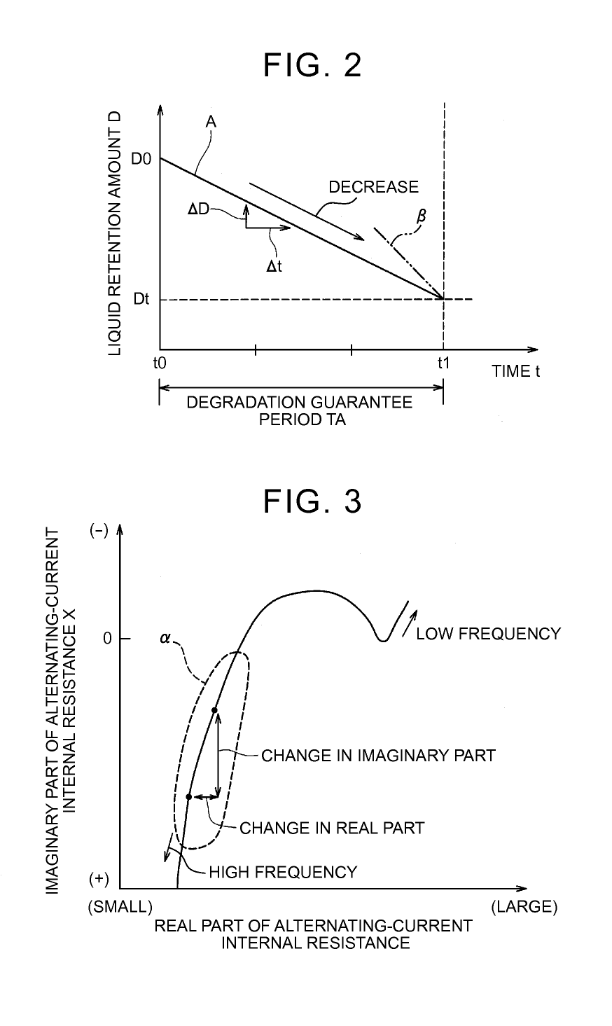

The liquid retention amount threshold for determining whether a used secondary battery is applicable to a reconstructed battery pack is set by using the correlation shown in FIG. 2. FIG. 2 shows the correlation between a liquid retention amount and an elapsed time, which is used to set the liquid retention amount threshold of the secondary battery, in the determination method. In FIG. 2, the abscissa axis represents time t, and the ordinate axis represents the liquid retention amount D of the separator in the secondary battery. As shown in FIG. 2, the liquid retention amount decreases with time.

It is assumed that a used secondary battery is used for a reconstructed battery pack. When a used secondary battery is used for a reconstructed battery pack, it is required not to guarantee that the used secondary battery is currently usable but to guarantee that the used secondary battery is usable during the period from t0 to t1. Time t0 is the current time point. Time t1 is the end time point of a predetermined degradation guarantee period TA that is set in advance. A liquid retention amount Dt is a lower limit liquid retention amount (degradation limit liquid retention amount) at or above which the function of the secondary battery is allowed to be guaranteed. A liquid retention amount D0 is a liquid retention amount at time t0. When the predetermined degradation guarantee period TA has elapsed from t0, the liquid retention amount D0 changes to the liquid retention amount Dt. The liquid retention amount D0 is the liquid retention amount threshold. That is, the liquid retention amount D0 is a liquid retention amount at which it is allowed to guarantee that the secondary battery is usable for the predetermined degradation guarantee period TA from now on.

The liquid retention amount threshold D0 is set by using the correlation between a liquid retention amount and time, shown in FIG. 2. A characteristic line that connects the liquid retention amount D0 at time t0 to the liquid retention amount D1 at time t1 is a liquid retention amount decrease characteristic. The slope (−ΔD/Δt) of the liquid retention amount decrease characteristic is the rate of decrease in the liquid retention amount. The predetermined degradation guarantee period TA, the degradation limit liquid retention amount Dt and the rate of decrease in the liquid retention amount may be obtained in advance for a secondary battery of the same type as the used secondary battery intended for determination.

For example, the rate of decrease in the liquid retention amount is obtained in advance through an experiment. When the secondary battery is mounted on a hybrid vehicle and is continuously used, charging and discharging of the secondary battery are repeated. A used battery pack is extracted at preset multiple operating time points and disassembled into battery cells of a plurality of used secondary batteries, and separators are extracted. The liquid retention amount is obtained by checking the percentage of liquid amount per predetermined area inside each extracted separator. In this way, the rate of decrease in the liquid retention amount is obtained from the correlation between a liquid retention amount and an elapsed time. For a vehicle-mounted secondary battery, the predetermined degradation guarantee period TA may be set in accordance with the type or traveling state of the vehicle.

The predetermined degradation guarantee period TA, the degradation limit liquid retention amount Dt and the rate of decrease in the liquid retention amount for the used secondary battery intended for determination are input to the computer in advance, and then D0 is calculated by using TA, Dt, the liquid retention amount, and the relational expression D0=Dt+|(ΔD/Δt)|×t. The calculated D0 is set as the liquid retention amount threshold. Thus, the liquid retention amount threshold D0 at the time point the predetermined degradation guarantee period TA before from Dt is set by using the rate of decrease. The liquid retention amount threshold D0 may be obtained by the types of the used secondary battery and is stored in a storage unit of the computer, the computer may load the liquid retention amount threshold D0 corresponding to a type as a result of input of the type of the used secondary battery, and the computer may set the loaded value as the liquid retention amount threshold.(ΔD/Δt) is constant in FIG. 2. However, when the rate of decrease nonlinearly changes with time, D0 may be calculated as D0=Dt+Σ{|(ΔD/Δt)|×Δt} while a time period is divided into small sections.

Subsequently, the correlation between a liquid retention amount and an alternating-current internal resistance value X for a secondary battery of the same type as the used secondary battery intended for determination is obtained in advance, and an alternating-current internal resistance value corresponding to the liquid retention amount threshold D0 is set as an alternating-current internal resistance threshold X0 (S12). It is difficult to externally check the liquid retention amount inside the used secondary battery intended for determination. The inventor carried out various experiments in order to obtain which measured value is adequate for being associated with a liquid retention amount, and found that not a direct-current internal resistance value but an alternating-current internal resistance value measured and acquired at the time of application of an alternating current having a predetermined measuring frequency to a secondary battery significantly relates to a liquid retention amount. When the alternating-current internal resistance value is large, the migration resistance of ions in an electrolytic solution is large. Therefore, it may be determined that the liquid retention amount is small. The direct-current internal resistance value is referred to as DCIR, and the alternating-current internal resistance value is referred to as ACIR. The predetermined measuring frequency is a frequency at which the degree of correlation between a liquid retention amount and an alternating-current internal resistance value for a secondary battery of the same type as the used secondary battery intended for determination is higher than or equal to a preset value. The alternating-current internal resistance value is an impedance value, and may be divided into a real part and an imaginary part. Particularly, to detect a change in the liquid retention amount, it is desirable to observe a change in the imaginary part.

FIG. 3 relates to an alternating-current impedance value that is the alternating-current internal resistance value of a nickel-metal hydride secondary battery. FIG. 3 is a Cole-Cole plot that shows the locus of a vector end at the time when the absolute value and phase of the alternating-current impedance value change on a complex plane while a measuring frequency is used as a parameter. The abscissa axis represents a real part, and the ordinate axis represents an imaginary part. As shown in FIG. 3, a change in the imaginary part is significantly larger than a change in the real part in a region in which the measuring frequency is high to some extent. In other words, the imaginary part has a higher detection sensitivity than the real part. Hereinafter, unless not specifically notified, the alternating-current internal resistance value indicates the value X of the imaginary part of the impedance value. The inventor identified that it is suitable to use 1 kHz as the predetermined measuring frequency (any one of frequencies within the dashed-line box α in FIG. 3) having a high degree of correlation between a liquid retention amount and an alternating-current internal resistance.

The real part of the impedance value may be used as the alternating-current internal resistance value. The absolute value |z| (=Ve/Ie) of the impedance value may be obtained from a detected value of an effective voltage Ve and a detected value of an effective current Ie, and the absolute value |z| may be used as the alternating-current internal resistance value.

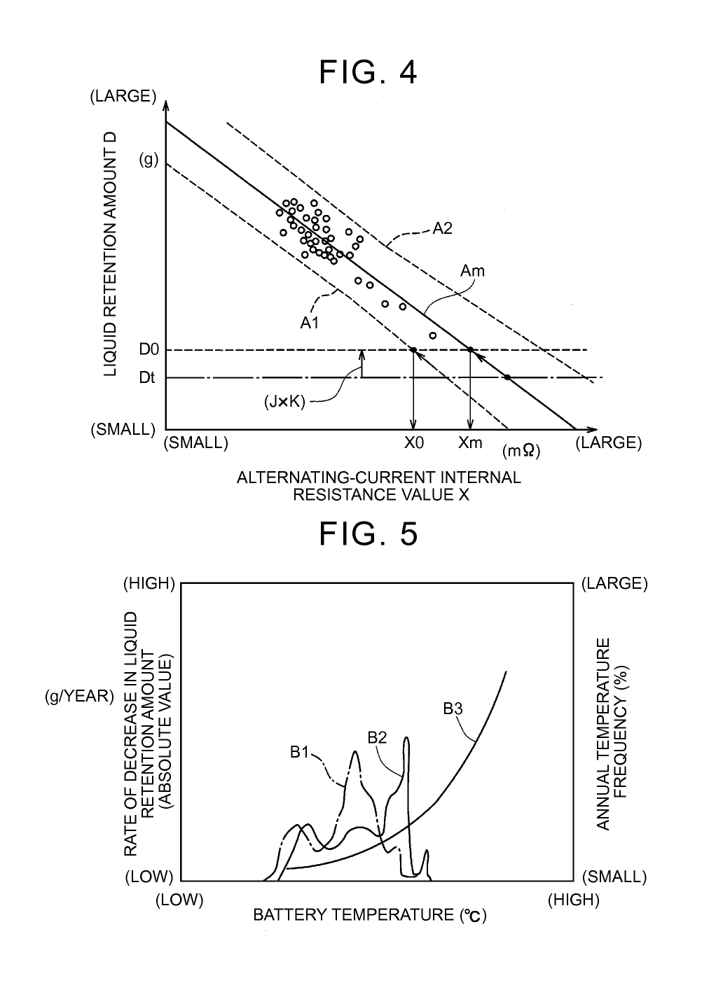

FIG. 4 is a graph that shows the correlation between liquid retention amounts D (g) obtained by disassembling 80 nickel-metal hydride secondary batteries and the alternating-current internal resistance values X (mΩ) of the secondary batteries. The continuous line Am indicates an average line at the time when 80 data are statistically processed and a correlation is obtained, and the dashed lines A1, A2 respectively indicate a lower limit line and an upper limit line for an internal resistance in a 3σ confidence interval with respect to the average line Am as a median. As shown in FIG. 4, as the liquid retention amount decreases, the alternating-current internal resistance value X indicates a larger value. An alternating-current internal resistance threshold Xm is a resistance value at the time when the travel distance of the vehicle on which the secondary batteries are mounted is an average travel distance that is one example of a degradation guarantee model. The alternating-current internal resistance threshold X0 is a resistance value in the case where the travel distance of the vehicle on which the secondary batteries are mounted is an average value +3σ, which is another example of the degradation guarantee model, and the liquid retention amount is an average value −3σ. Therefore, when the alternating-current internal resistance value X is Xm, the alternating-current internal resistance value X corresponds to the liquid retention amount threshold D0 in the case where the vehicle is used over an average travel distance. When the alternating-current internal resistance value X is X0, the alternating-current internal resistance value X corresponds to the liquid retention amount threshold D0 in the case where the vehicle is used over a substantially longest travel distance.

The rate of decrease in the liquid retention amount described above is not limited to the case where a constant value is used. For example, as will be described below, a temperature-related rate of decrease in the liquid retention amount may be used as the rate of decrease in the liquid retention amount. The temperature-related rate of decrease changes in association with a temperature. For a secondary battery of the same type as the used secondary battery intended for determination, a liquid retention amount at the time point the predetermined degradation guarantee period TA before from the degradation limit liquid retention amount Dt may be set as the liquid retention amount threshold D0. The degradation limit liquid retention amount Dt is a liquid retention amount at the time point t1 at which it is determined that the secondary battery degrades. The predetermined degradation guarantee period TA is set in advance by using the temperature-related rate of decrease.

For example, the alternating-current internal resistance threshold X0 in FIG. 4 may be set as a resistance value that corresponds to the liquid retention amount threshold D0 for a severe-use user model. The severe-use user model is used in a high-temperature area, and the annual travel distance of the severe-use user model is substantially the longest. The high-temperature area is assumed as, for example, a high-temperature area, such as the North America desert area, or a high-temperature area, such as South America and Africa.

FIG. 5 shows the correlation between a battery temperature and an annual temperature frequency, which is used in the case where the amount of decrease in the liquid retention amount during the predetermined degradation guarantee period TA is obtained and the correlation between a battery temperature and the rate of decrease in the liquid retention amount of the secondary battery in the determination method according to the present embodiment. In FIG. 5, the alternate long and short dashed line B1 indicates the correlation between an annual temperature frequency and the temperature of the secondary battery for an average-use user model. The average-use user model is used in an average-temperature area, and the annual travel distance of the average-use user model is average. In FIG. 5, the continuous line B2 indicates the correlation between the annual temperature frequency of the secondary battery and the temperature of the secondary battery for the severe-use user model. The severe-use user model is used in the high-temperature area, and the annual travel distance of the severe-use user model is substantially the longest. The annual temperature frequency is the annual distribution of secondary battery temperature in percentage (%). When B1 and B2 in FIG. 5 are compared with each other, it appears that the frequency at which the secondary battery is used on a high-temperature side is higher in the case of B2 than in the case of B1.

In FIG. 5, the continuous line B3 indicates the correlation between a temperature-related rate of decrease and the temperature of the secondary battery. The temperature-related rate of decrease is the rate of decrease in the liquid retention amount in the case where the rate of decrease in the liquid retention amount changes with the temperature of the secondary battery.

As shown in FIG. 5, for the temperature-related rate of decrease indicated by the continuous line B3, the rate of decrease in the liquid retention amount increases as the temperature of the secondary battery increases. For example, in the case of the severe-use user model indicated by the continuous line B2 in FIG. 5, the secondary battery is used on a higher temperature side than the secondary battery is used in the case of the average-use user model indicated by B1. Therefore, as indicated by the alternate long and two-short dashed line β in FIG. 2, the rate of decrease in the liquid retention amount increases. Thus, when the predetermined degradation guarantee period TA is set as in the case of another user model, the liquid retention amount threshold D0 needs to be set so as to be higher than D0 in FIG. 2. At this time, as shown in FIG. 4, it appears that the alternating-current internal resistance value X decreases as the liquid retention amount threshold D0 increases. For example, when the secondary battery is used in accordance with the severe-use user model indicated by the continuous line B2 in FIG. 5, the rate of decrease V may be obtained from the temperature-related rate of decrease by using the average temperature of the secondary battery, and then the liquid retention amount threshold D0 at the time point the predetermined degradation guarantee period before from the degradation limit liquid retention amount Dt may be obtained by using the rate of decrease V. After that, the alternating-current internal resistance threshold X0 that corresponds to D0 is set. At this time, X0 is used as the alternating-current internal resistance threshold of the severe-use user model. Because the alternating-current internal resistance threshold X0 is set in accordance with the substantially severest user model, a guarantee of the secondary battery against degradation is provided under the substantially most strict condition, and the single alternating-current internal resistance threshold X0 is allowed to be used to provide a guarantee of all the used secondary batteries against degradation. Therefore, it is easy to execute the process of determining whether each of the used secondary batteries is applicable to a reconstructed battery pack. For example, when the imaginary part of the impedance value is used at a measuring frequency of 1 kHz, 7.00 mΩ is set as the resistance threshold X0 of the severe-use user model.

As another example of the method of setting the liquid retention amount threshold D0 by using the temperature-related rate of decrease, for example, the distribution of the annual temperature frequency of the severe-use user model indicated by the continuous line B2 in FIG. 5 and the rate of decrease in the liquid retention amount, indicated by the continuous line B3, may be integrated in all the secondary battery temperature regions in which the secondary battery is assumed to be used, and then D0 may be set by using the obtained calculated value of the annual amount of decrease in the liquid retention amount (Jg/year). By multiplying the calculated amount of decrease in the annual liquid retention amount (Jg/year) by the number of years (K years) of the predetermined degradation guarantee period TA ((J×K) g), the liquid retention amount at the time when (J×K) g is added to the degradation limit liquid retention amount Dt is set as the liquid retention amount threshold D0. In this way, the liquid retention amount threshold at the time point the predetermined degradation guarantee period TA before is set by using the rate of decrease in the liquid retention amount. At this time as well, the alternating-current internal resistance threshold X0 corresponding to the liquid retention amount threshold D0 is set. At this time, when the alternating-current internal resistance value X of the battery module that is the used secondary battery is acquired, the liquid retention amount and rate of decrease in the liquid retention amount per battery cell may be used as the liquid retention amount D in FIG. 4 and the rate of decrease in the liquid retention amount in FIG. 5.

Next, referring back to FIG. 1, the alternating-current internal resistance value X of the used secondary battery intended for determination is acquired (S14). Specifically, by applying the alternating-current signal having the predetermined measuring frequency to the used secondary battery, the alternating-current internal resistance value X is measured and acquired from a voltage response of the used secondary battery. On the basis of the result of comparison between the acquired alternating-current internal resistance value X and the alternating-current internal resistance threshold X0, it is determined whether the used secondary battery intended for determination is applicable to a reconstructed battery pack. More specifically, it is determined whether the acquired alternating-current internal resistance value X is smaller than the alternating-current internal resistance threshold X0 (S16). When affirmative determination is made in S16, it is determined that the used secondary battery intended for determination is applicable to a reconstructed battery pack (S18), and the process is ended. On the other hand, when negative determination is made in S16, it is determined that the used secondary battery intended for determination is not applicable to a reconstructed battery pack, and the used secondary intended for determination is discarded or recycled. That is, the used secondary battery is disassembled and is processed so that usable parts are recycled (S20), and then the process is ended.

In determining in S18 whether the used secondary battery intended for determination is applicable to a reconstructed battery pack, it may be determined whether the used secondary battery is applicable to a reconstructed battery pack on the basis of not only affirmative determination of S16 but also fulfillment of another reconstructed battery pack applicability condition. For example, as another reconstructed battery pack applicability condition, a condition that the direct-current internal resistance value measured for the used secondary battery is smaller than or equal to a predetermined value, a condition that a terminal voltage value measured for the used secondary battery is higher than or equal to a predetermined voltage value or a condition that there is no damage, such as dent, crack and bend, in visual inspection on the used secondary battery. When the direct-current internal resistance value of the used secondary battery exceeds the predetermined value, when the terminal voltage value of the used secondary battery is lower than the predetermined voltage value or when it is determined that there is damage in the used secondary battery, the used secondary battery is discarded or recycled in S20 as in the case where negative determination is made in S16.

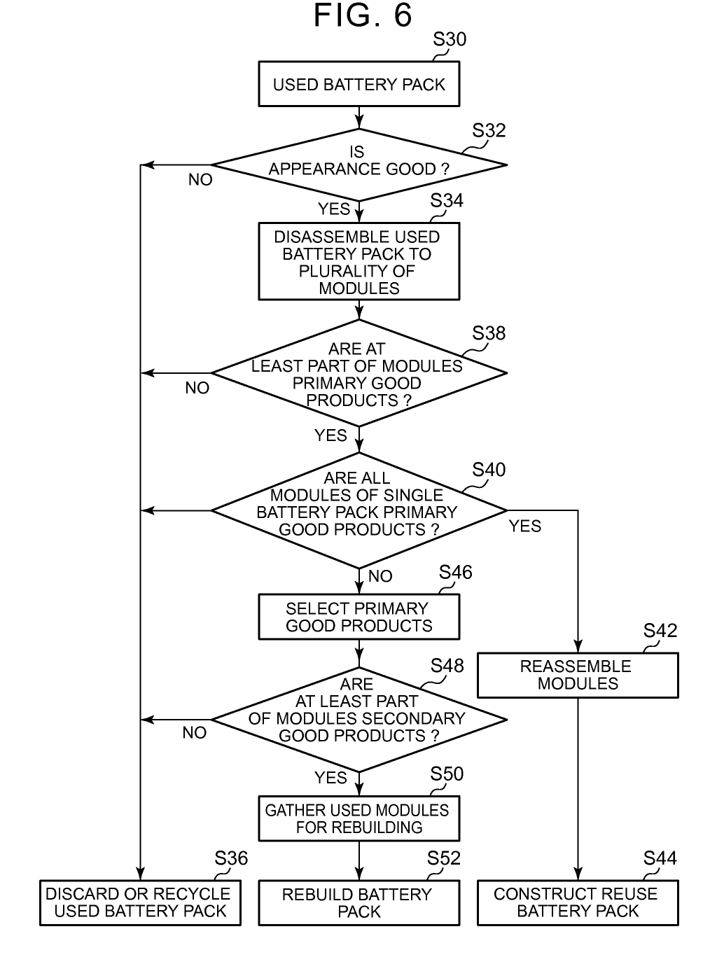

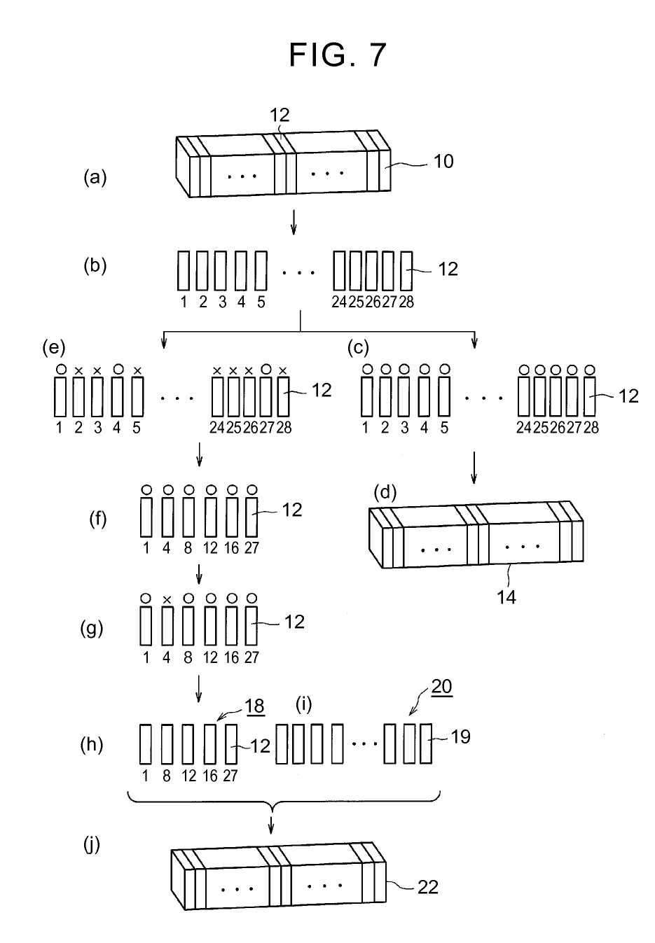

Next, a rebuilding method that is the reconstruction method for a reconstructed battery pack will be described with reference to FIG. 6 and FIG. 7 by using the reconstructed battery pack applicability determination for the used secondary battery, described in FIG. 1. FIG. 6 shows a flowchart that is used to carry out a rebuilding method and a reuse battery pack construction method according to the present embodiment. FIG. 7 is a view that shows, in time sequence, a state where a used battery pack 10 is disassembled, a used secondary battery 12 that allows a guarantee against degradation is selected and a reconstructed battery pack is reconstructed in accordance with the rebuilding method shown in FIG. 6.

The rebuilding method and the construction method for a reuse battery pack, shown in FIG. 6, will be described with reference to FIG. 7. The rebuilding method according to the present embodiment is a reconstruction method in which the used secondary batteries 12 that allow a guarantee against degradation are selected from among a plurality of the used secondary batteries 12 that constitute the used battery pack 10 by determining whether each used secondary battery 12 allows a guarantee against degradation as the secondary battery, and a rebuilt battery pack 22 that is a reconstructed battery pack is reconstructed. Initially, used battery packs 10 ((a) in FIG. 7) used for a certain period are retrieved from users or collection agencies by a reconstruction division that reconstructs a battery pack (S30) and are prepared for reconstruction. Subsequently, the used battery pack 10 is visually inspected in S32. In the visual inspection, it is determined whether the used battery pack 10 has no damage and good appearance. When affirmative determination is made in S32, the process proceeds to S34. When negative determination is made in S32, the used battery pack 10 is discarded or recycled in S36. In S34, the used battery pack 10 is disassembled into a plurality of (28 in the illustrated example) used secondary batteries 12 ((b) in FIG. 7). In FIG. 7, a used battery module formed of a plurality of used battery cells is shown as the used secondary battery 12. Each individual used secondary battery 12 is distinguished from each other with reference numerals below each used secondary battery 12.

Subsequently, in S38, as a primary good/bad determination, the reconstructed battery pack applicability determination shown in FIG. 1 is carried out for all the 28 used secondary batteries 12. Specifically, as in the case of S14 in FIG. 1, the alternating-current internal resistance value X is acquired for each of the plurality of intended used secondary batteries 12, and then, as in the case of S16, it is determined whether each acquired alternating-current internal resistance value X is smaller than the alternating-current internal resistance threshold X0. The processes of S10, S12 in FIG. 1 may be carried out only once in common among the used secondary batteries 12 or may be carried out in advance of S30 in FIG. 6. In the primary good/bad determination in S38, it is determined whether at least part of the acquired values X of the 28 used secondary batteries 12 are smaller than the alternating-current internal resistance threshold X0 (X<X0).

When affirmative determination is made in S38, the used secondary batteries 12 of which the acquired value X is smaller than the alternating-current internal resistance threshold X0 are determined as primary good products, and the process proceeds to S40. In part of FIG. 7, such as (b) and (c) in FIG. 7, circle mark is attached above the used secondary batteries 12 that are the primary good products or secondary good products (described later). Cross mark is attached above the used secondary batteries 12 that are determined as bad products.

When negative determination is made in S38, all the used secondary batteries 12 are primary bad products, so the process of S36 is carried out.

In S40, it is determined whether one-pack used secondary batteries 12 that are all obtained from the single used battery pack 10 are primary good products. When affirmative determination is made in S40, all the used secondary batteries 12 are primary good products as shown in (c) of FIG. 7. At this time, it is determined that reassembling of all the used secondary batteries 12 to a reuse battery pack 14 ((d) in FIG. 7) that is formed by reconstructing all the used secondary batteries 12 is allowed. The used secondary batteries 12 are gathered and reassembled (S42), and then the reassembled battery pack is shipped to a dealer and is reused as the reuse battery pack 14 (S44). In determination of S38, as in the case of determination of S18 in FIG. 1, fulfillment of another reconstructed battery pack applicability condition may be set as a condition for determining the used secondary battery as a primary good product.

When negative determination is made in S40, only part of the used secondary batteries 12 that constitute the used battery pack 10 are primary good products that allow a guarantee against degradation, as shown in (e) of FIG. 7. Therefore, as shown in (f) of FIG. 7, the process of selecting the used secondary battery 12 that is the primary good product is carried out in S46. In S48, before the used secondary batteries 12 selected as the primary good products are used as constituent products of a rebuilt battery pack 22 ((j) in FIG. 7), the alternating-current internal resistance values X are acquired again. It is determined whether each of the acquired alternating-current internal resistance values X acquired again is smaller than the alternating-current internal resistance threshold X0. Thus, it is determined whether each used secondary battery 12 is a secondary good product that is usable for the rebuilt battery pack 22 ((g) in FIG. 7). The reason why good/bad determination is carried out twice on the same used secondary battery 12 is to exclude the used secondary battery 12 that is not a good product any more as a result of a long-term storage period. This is because a storage period becomes a long term from primary good/bad determination to reconstruction when a single rebuilt battery pack 22 is reconstructed of used secondary batteries 12 selected from among used secondary batteries of a plurality of different used battery packs 10.

When affirmative determination is made in S48, a used battery group 18 and a used battery group 20 that are formed of the used secondary batteries 12 that are secondary good products are gathered in number for constructing a single used battery pack (S50) ((h) in FIG. 7). The used battery group 20 is a used battery group formed of used batteries 19 disassembled from one or more used battery packs (not shown) other than those of the used battery group 18 and selected as secondary good products. The gathered used battery groups 18, 20 are combined together and reconstructed (S52) ((j) in FIG. 7), and the combined used battery groups are shipped to a dealer as the rebuilt battery pack 22. When negative determination is made in S48, the process of S36 is carried out, and the used secondary batteries 12 that are secondary bad products are discarded or recycled. Determination as to whether the primary good product is usable as the secondary good product may include determination as to whether overall specifications set in advance to apply the used secondary battery 12 to the rebuilt battery pack 22 are satisfied. For example, in determination of S48 as well, as in the case of determination of S18 in FIG. 1, fulfillment of another reconstructed battery pack applicability condition may be included as a condition, and it may be determined whether the used secondary battery 12 is the secondary good product and is applicable to the rebuilt battery pack 22.

With the determination method for the used secondary battery 12 according to the present embodiment, it is possible to determine whether the used secondary battery 12 is suitable for the rebuilt battery pack 22 on the basis of the correlation with the liquid retention amount. Because whether reconstruction is applicable is determined on the basis of the acquired alternating-current internal resistance value, it is possible to simply determine whether reconstruction is applicable on the basis of the correlation with the liquid retention amount in a nondestructive manner. A liquid retention amount at the time point the predetermined degradation guarantee period TA before from the liquid retention amount Dt by using the rate of decrease in the liquid retention amount is set as the liquid retention amount threshold D0. The liquid retention amount Dt is a liquid retention amount at which it is determined that a secondary battery of the same type as the used secondary battery 12 intended for determination degrades. Therefore, it is possible to select the used secondary battery 12 that is not determined to be degraded over a period from the current time to the end time of the predetermined degradation guarantee period TA. Thus, it is possible to provide the determination method that is further suitable for determination as to whether the used secondary battery 12 is applicable to the rebuilt battery pack 22. In the cell degradation determination method described in JP 2011-257314 A, it is only determined whether the secondary battery cell is currently degraded and a future degradation is not determined, so it is not suitable for determination as to whether the used secondary battery is applicable to a reconstructed battery pack.

With the reconstruction method for a reconstructed battery pack according to the present embodiment, it is possible to provide a reconstruction method that is suitable for selecting the used secondary battery 12 applicable to the rebuilt battery pack 22 on the basis of the correlation with the liquid retention amount and then reconstructing the rebuilt battery pack 22.

The invention is not limited to the above-described embodiment. The invention encompasses the technical scope of the invention recited in the appended claims and all the modifications and improvements that are not apart from the scope of the invention.

What is claimed is:

1. A determination method for a used secondary battery by a computer, the used secondary battery including a separator, the determination method comprising:
comparing, by the computer, an alternating-current internal resistance threshold with an alternating-current internal resistance value, the alternating-current internal resistance value being acquired by applying an alternating-current signal having a predetermined frequency to a first secondary battery, the first secondary battery being the used secondary battery intended for determination, the alternating-current internal resistance threshold being a value corresponding to a liquid retention amount threshold of the separator of the first secondary battery, the liquid retention amount threshold being a liquid retention amount of a separator of a second secondary battery, the second secondary battery being a secondary battery of the same type as the used secondary battery intended for determination, the liquid retention amount threshold being a preset value; and
determining, by the computer, whether the first secondary battery is allowed to be applied to a reconstructed battery pack, the reconstructed battery pack being a battery pack formed of a plurality of used secondary batteries.

2. The determination method according to claim 1, wherein
the liquid retention amount threshold is a value that is set on the basis of a rate of decrease in the liquid retention amount, and
the liquid retention amount threshold is set as the liquid retention amount at a time point a predetermined degradation guarantee period before from the liquid retention amount at a time point at which the second secondary battery is determined to degrade, and the degradation guarantee period is a period during which a usable state of the second secondary battery is guaranteed.

3. The determination method according to claim 1, wherein
the alternating-current internal resistance value is a value that is set in a state where an alternating-current internal resistance value corresponding to the liquid retention amount threshold is set as the alternating-current internal resistance threshold, and
the liquid retention amount threshold is a value that is set by obtaining in advance a correlation between the liquid retention amount and the alternating-current internal resistance value for the second secondary battery.

4. The determination method according to claim 1, wherein the alternating-current internal resistance value is acquired from a voltage response of the first secondary battery through application of the alternating-current signal to the first secondary battery, the alternating-current signal is an alternating-current signal having a frequency at which a degree of correlation between the liquid retention amount and the alternating-current internal resistance value for the second secondary battery is larger than or equal to a preset value.

5. A reconstruction method for a reconstructed battery pack, the reconstruction method comprising:
carrying out the determination method according to claim 1 on a used secondary battery; and
reconstructing a battery pack from a plurality of the first secondary batteries that have been determined to be allowed to be applied to the reconstructed battery pack.

6. A reconstruction method for a reconstructed battery pack, the reconstructed battery pack being a battery pack that is reconstructed of predetermined used secondary batteries, each of the predetermined used secondary batteries being a used secondary battery that allows a guarantee against degradation, the secondary battery that allows a guarantee against degradation being selected from among a plurality of used secondary batteries that constitute a used battery pack by determining by a computer whether the used secondary battery is a secondary battery that allows a guarantee against degradation, the reconstruction method comprising:
(a) setting, by the computer, an alternating-current internal resistance value corresponding to a liquid retention amount threshold of a first secondary battery as an alternating-current internal resistance threshold, the first secondary battery being the used secondary battery intended for determination, the liquid retention amount threshold being a value that is set on the basis of a rate of decrease in the liquid retention amount, the liquid retention amount threshold being set as the liquid retention amount at a time point a predetermined degradation guarantee period before from the liquid retention amount at a time point at which the second secondary battery is determined to degrade, the second secondary battery being a secondary battery of the same type as the used secondary battery intended for determination, the liquid retention amount being a liquid retention amount of a separator of the second secondary battery, the degradation guarantee period being a period during which a usable state of the second secondary battery is guaranteed;
(b) selecting, by the computer, the used secondary battery, of which the alternating-current internal resistance value is smaller than the alternating-current internal resistance threshold, as the used secondary battery that allows a guarantee against degradation, the alternating-current internal resistance value being the alternating-current internal resistance value of the first secondary battery; and
(c) reconstructing a battery pack by using the selected used secondary batteries.

7. The reconstruction method according to claim 6, wherein
the alternating-current internal resistance value is acquired for each of the plurality of used secondary batteries intended for determination,
the computer determines the used secondary battery, of which the alternating-current internal resistance value is smaller than the alternating-current internal resistance threshold, as a primary good product out of all the first secondary batteries, and
the computer determines the used secondary battery, of which the alternating-current internal resistance value before being used for a reconstructed battery pack is smaller than the alternating-current internal resistance threshold, as a secondary good product out of the used secondary battery determined as the primary good product, the secondary good product is a secondary battery that is usable for a reconstructed battery pack out of the primary good product.

8. The reconstruction method according to claim 7, wherein determination as to whether the primary good product is usable as the secondary good product includes determination as to whether overall specifications determined in advance to apply the used secondary battery to the reconstructed battery pack are satisfied.
